(19) United States
(12) Patent Application Publication
(10) Pub. No.: US 2019/0106322 A1
(43) Pub. Date: Apr. 11, 2019

(54) LOW COST, LOW PROFILE, CERAMIC BUTTON SENSOR PACKAGING

(71) Applicant: DUNAN SENSING, LLC, SAN JOSE, CA (US)

(72) Inventors: DANNY (DUY) DO, SAN JOSE, CA (US); KEVIN (CUONG) NGUYEN, SAN JOSE, CA (US); YING CHEN, SAN JOSE, CA (US); JITENDRA PATIL, SAN JOSE, CA (US)

(21) Appl. No.: 15/727,342

(22) Filed: Oct. 6, 2017

(51) Int. Cl. B81C 1/00; H01L 23/15; H01L 23/00; H05K 3/32; H05K 1/18; B81B 7/00; H05K 1/03

(52) U.S. Cl. CPC B81C 1/00301; H01L 23/15; H01L 23/562; H05K 3/32; B81B 2207/096; H05K 1/185; B81B 7/0006; H05K 1/0306; B81B 2207/092; H05K 1/181

(57) ABSTRACT

Sensor packages and methods of assembling sensor packages are provided. A preferred embodiment comprises: a ceramic base comprised of a platform and walls that extend up from the platform around the periphery of the platform to form a cavity; a sensor mounted to the ceramic base; a circuit board mounted down into the cavity wherein the circuit board has a hole through the board that aligns with the sensor such that the sensor is exposed to a top side of the circuit board through the hole; a plurality of electrical connections between the sensor and the circuit board; a plurality of electrical pins mounted to the circuit board and extending up above the walls of the ceramic base; and a cap mounted down into the cavity over the top of the circuit board, the cap including a window that allows the electrical pins to pass through the cap.

### FIELD

The present patent document relates generally to methods of packaging sensor and packages therefor. More specifically, the present patent document relates to methods of packaging Micro-electro-mechanical systems (MEMS) pressure sensors and packages for the same.

### BACKGROUND

Sensors are used in a wide variety of applications including, for example, in automotive, aerospace, industrial and medical applications. As manufacturing techniques continue to allow smaller and smaller sensor designs, sensors are becoming even more widespread. Due to their small size, the use of MEMS sensors is becoming commonplace in areas never thought possible. In all these various applications, the sensors must somehow be mounted or packaged to allow them to perform properly. An effective package and packaging technique must address a number of engineering requirements and is preferably easily manufactured at as low a cost as possible.

Packaging of MEMS sensors is an important part of a successful implementation. Sensor design has rapidly improved in recent times. Sensor packaging must keep pace. US Patent Publication No. 2015/0339384 filed on Jun. 20, 2014, discloses a plurality of embodiments for sensor packages and that application is incorporated herein by reference in its entirety.

U.S. patent application Ser. No. 15/220,048 filed on Jul. 26, 2016, provides additional embodiments of sensor packages and methods of packaging sensors and that application is also incorporated herein by reference in its entirety.

The current application provides a number of improvements to the sensor packaging design and methods of packaging a sensor to allow for ease of manufacture and cost reductions. One main drive of the sensor package designs disclosed herein, is to allow for a sensor package design that can be manufactured with standardized manufacturing equipment. Moreover, the embodiments disclosed herein minimize variations in design and accommodate various applications and requirements with minimal differences in the assembly process.

### SUMMARY OF THE EMBODIMENTS

Objects of the present patent document are to provide improved methods for packaging a sensor and packages therefor. To this end, a sensor package is provided. The sensor package comprises: a ceramic base wherein the base is comprised of a platform and walls that extend up from the platform around the periphery of the platform to form a cavity; a sensor mounted to the ceramic base on a bottom surface of the cavity; a circuit board mounted down into the cavity wherein the circuit board has a hole through the board that aligns with the sensor such that the sensor is exposed to a top side of the circuit board through the hole; a plurality of electrical connections between the sensor and the circuit board; a plurality of electrical pins mounted to the circuit board and extending up above the walls of the ceramic base; and a cap mounted down into the cavity over the top of the circuit board, the cap including a window that allows the electrical pins to pass through the cap and extend above the cap.

In preferred embodiments, the cap is made from a thermal plastic and the base is made from Alumina Oxide. The cap may be color coded to reflect different applications or pressure ranges of the enclosed pressure sensor.

The sensor packages designed herein are designed for use with MEMS sensors and in particular MEMS pressure sensors. However, the packages and packaging techniques taught herein may be used with any type of sensor.

In some embodiments, the ceramic base may be made from two pieces coupled together. In embodiments with a base made from a plurality of pieces, the first piece comprises the platform and the second piece comprises the walls. In embodiments where the base is cylindrically shaped, the walls may be thought of as a ring and referred to as such.

In some embodiments, a thermal sensor may be mounted to the base along with the sensor. Preferably, the thermal sensor is a thermistor. In various different embodiments, the thermal sensor may be mounted to the interior or exterior of the sensor package and in particular the base.

In embodiments where the thermal sensor is mounted to the interior of the sensor package, the thermal sensor may be mounted on the bottom surface of the cavity. During assembly, the thermal sensor is aligned with the hole in the circuit board such that the thermal sensor is exposed to the top side of the circuit board through the hole just like the sensor.

In embodiments where the thermal sensor is mounted to the exterior of the sensor package, the thermal sensor may be mounted on a bottom surface of the platform portion of the base and vias through the platform can provide electrical communication between the thermal sensor and the circuit board on the interior of the sensor package.

In order to provide electrical connection to the thermal sensor, some embodiments use contact pads. In some embodiments, a first set of electrical contact pads are placed on the bottom surface of the cavity of the base and a corresponding second set of electrical contact pads are placed on the circuit board. The first and second sets of electrical contact pads are aligned to provide electrical communication between the circuit board and the thermal sensor.

Although generally the components can be any shape, preferably the base, cap and circuit board are cylindrical.

In another aspect of the present patent document, a method of assembling a sensor in a sensor package is provided. In preferred embodiments, the method comprises the steps of: soldering a sensor to a bottom surface of a cavity in a ceramic base wherein the base is comprised of a platform and walls that extend up from the platform around the periphery of the platform to form the cavity; epoxying a circuit board down into the cavity of the base such that a hole in the circuit board surrounds the sensor; electrically connecting the sensor to the circuit board with bond-wires; and epoxying a cap down into the cavity of the base such that the cap covers the circuit board wherein the cap has a window and connection pins mounted to the circuit board extend up past the top of the walls and the cap through the window.

In some embodiments, the ceramic base is made from two pieces, a first piece comprises the platform and a second piece comprises the walls and the method further comprises coupling the platform to the walls. Preferably, the platform is coupled to the walls using epoxy or RTV.

In embodiments that include thermal sensors, the method may further comprise placing the circuit board in electrical communication with the thermal sensor by aligning a first set of electrical contact pads on the bottom surface of the cavity of the base and a corresponding second set of electrical contact pads on the circuit board.

### BRIEF DESCRIPTION OF THE DRAWINGS

FIG. 1 illustrates an isometric view of one embodiment of a sensor package.

FIG. 2 illustrates a top down view of the sensor package of FIG. 1 without the cap shown.

FIG. 3 illustrates an isometric exploded view of the embodiments of a sensor package of FIGS. 1 and 2.

FIG. 4 illustrates an isometric explode view of a second embodiment of a sensor package.

FIG. 5 illustrates a top down view of a third embodiment of a sensor package without the cap shown.

FIG. 6 illustrates an isometric exploded view of the embodiment of a sensor package of FIG. 5.

FIG. 7 illustrates a top down view of a fourth embodiment of a sensor package without the cap shown.

FIG. 8 illustrates an isometric exploded view of the embodiment of a sensor package of FIGS. 7 and 9.

FIG. 9 illustrates a bottom up view of the embodiment of a sensor package of FIGS. 7 and 8.

### DETAILED DESCRIPTION OF THE PREFERRED EMBODIMENTS

The present patent document discloses sensor packages and methods of packaging a sensor that are more easily manufactured and are more cost effective. The novelty in the designs is not only in each single design individually but in the collective four designs. The four designs share many of the same parts and configurations allowing different types of sensor packages to be assembled with the fewest number of parts.

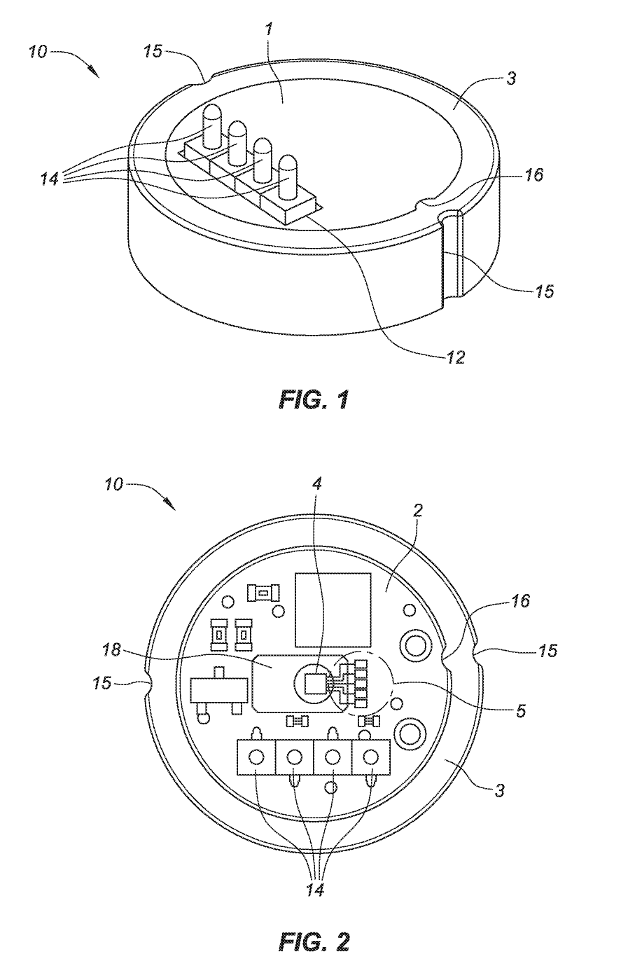

FIG. 1 illustrates an isometric view of one embodiment of a sensor package 10. As may be seen in FIG. 1, the sensor package 10 comprises, a base 3, and a cap 1. The cap 1 includes a hole/window 12 for the connection pins 14 to protrude through. The connection pins 14 are mounted to a circuit board inside the sensor package 10 and protrude through the window 12 to the exterior of the sensor package 10. In a preferred embodiment, the cap 1 includes just a single window 12 that allows all the connection pins to protrude through. In other embodiments, the cap 1 may include more than one window 12. In the embodiment shown in FIG. 1, the window 12 is a single rectangular shaped window 12 that allows 4 pins and their bases to protrude through. In a preferred embodiment, the pins are 4-pin headers (2 mm pitch) and are surfaced mounted to the PCB board. However, in other embodiments, other types of pins and other mounting techniques may be used.

As may be seen in FIG. 1, the base 3 is generally cylindrical. Although the overall shape of the sensor package 10, including the base 3, may be other shapes, the preferable shape is cylindrical. The outside of the base 3 may include a mechanical mating interface 15. In the embodiment shown in FIG. 1, two opposing slots are cut down the outside walls of the base 3 to aid in alignment into upper level assemblies.

As used herein, the term “mechanical mating interface” means an interface that is a groove, cut, channel slot or other depression with a corresponding protrusion on another part. A “mechanical mating interface” provides mechanical alignment of two parts. This should be contrasted with a “mating interface.” A “mating interface” is simply two interfaces that are designed to be mated together.

The embodiment of a mechanical mating interface 15 shown in the base 3 is a slot. However, the mechanical mating interface 15 may be a groove, channel, depression or other type of mechanical mating interface 15. On the inside of the base 3 another mechanical mating interface 15 aligns the cap with the base. The mechanical mating interface on the inside of the base 3, is a protrusion. The protrusion may be any type of protrusion. The protrusion should be sized and shaped such that it is reciprocal and may receive the corresponding mechanical mating interface on the other piece. It should be understood that a mechanical mating interface may be a groove or protrusion as long as the reciprocal mechanical mating interface is the opposite. In the embodiment, shown in FIGS. 1 and 2, a slot is used on the outside of the base 3 and the outside of the cap 1 and a protrusion is used on the inside of the base 3. However, the claims requiring only a mechanical mating interface would still be infringed even if a protrusion is used where a groove is shown and vice versa. To this end, the term “mechanical mating interface” is intended to cover both embodiments.

In various embodiments, any number of mechanical mating interfaces may be used between the base 3, the cap 1 and the circuit board 2. In the embodiment shown in FIGS. 1 and 2, two slots are shown on the outside of the base 3 and one protrusions is shown on the inside of the base 3. Grooves are also shown on the outside of the cap 1 and the outside of the circuit board 2. In other embodiments, a single mechanical mating interface or more than two mechanical mating interfaces may be used.

As may be seen, the shape of the base 3 is generally cylindrical but is cup shaped in that a concentric recess or cavity is bored down into the base 3. The base may be generally thought of as comprising the platform, which is the flat bottom portion of the base, and the walls, which extend up from the platform around the periphery. The cap 1 is also cylindrically shaped and sits down into the cavity such that the top surface of the cap 1 sits flush with the top surface of the base 3. As may be seen in FIG. 1, the window 12 fits over the pins 14 such that the pins 12 stick through the cap 1 and extend above the top surface of both the cap 1 and the base 3.

As may be appreciated, the interior of the base 3 may also have a mechanical mating interface to allow alignment of the cap 1. As shown in FIG. 1, the base 6 includes a rounded protrusion 16 that runs vertically from the bottom interior surface to the top surface of the base. The cap 1 has a matching slot such that the cap 1 can only be assembled to the base in a single configuration.

In preferred embodiments, the base 3 is made from Alumina Oxide. In an even more preferred embodiment the Alumina Oxide is 96% Al₂O₃. In other embodiments, other materials may be used for the base 3. In some embodiments, the base 3 may be referred to as a cup.

In preferred embodiments, the cap 1 is made from a thermal plastic. In some embodiments, the cap may be color coded for different applications and pressure ranges. In other embodiments, other materials may be used for the cap 1 and color coding of the cap 1 is not a requirement. The cap 1 may be coupled to the base 3 using epoxy. Other connection types may also be used including interference fit, clips, clamps or any other type of connector.

FIG. 2 illustrates a top down view of the sensor package 10 of FIG. 1 without the cap 1. As may be seen in FIG. 2, a circuit board 2 sits down inside the base 3. In preferred embodiments, the circuit board 2 is a printed circuit board (PCB). In the embodiment shown in FIG. 2, the pins 14 are mounted directly to the circuit board 2. The circuit board 2 preferably includes the electronics needed to support the sensor 4. The electronics may include signal conditioning electronics along with other supporting sensor electronics.

Similar to the cap 1, the circuit board 2 may include a slot or protrusion to ensure correct assembly. In the embodiment of FIG. 2, the circuit board 2 includes a slot that aligns with the protrusion 16 made in the base 3. To this end, the cap 1 and the circuit board 2 may both be aligned using a single protrusion 16 in the base 3.

The sensor is shown in FIG. 2 as element 4. In the embodiments described herein, the sensor 4 is coupled to the base 3. Preferably, the sensor 4 is soldered directly to the base 3. In preferred embodiments, the sensor 4 may be a MEMS sensor and even more preferably a MEMS pressure sensor; however, in other embodiments, any type of sensor may be used including piezoelectric sensors, digital sensors or any type of transducer sensor, just to name a few.

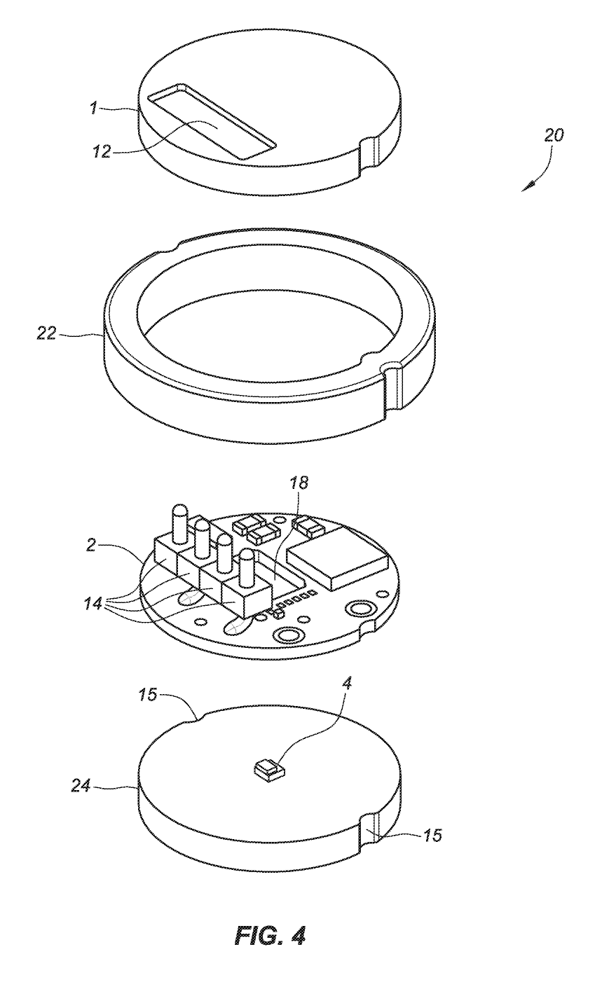

The senor 4 is mounted to the base 3 and the circuit board 2 has a window/hole 18 through the circuit board 2 to allow access to the sensor 4 from the top side of the circuit board 3. As may be seen in FIG. 4, the sensor 4 is mounted in the middle of the base 3 on the bottom of the cavity. Although other configurations are possible, mounting the sensor 4 in the middle of the base 3 is preferred. The window 18 in the circuit board 2, needs to be positioned to match the location of the sensor 4. To this end, the window 18 in the circuit board 2 is also preferably in the middle. In the embodiment shown in FIG. 2, a single rectangular window 18 is used to allow access to the sensor 4. However, any shape window 18 may be used including round, hexagon, pentagon, oval, square or any other shape.

As may be appreciated, the electronics on the circuit board 2 need to be in electrical communication with the sensor 4. In the embodiments shown herein, the sensor 4 is electrically connected to the electronics of the circuit board 2 with bond-wires. A plurality of bond-wires 5 connect the circuit board 2 to the sensor 4. In preferred embodiments, the bond-wires 5 are aluminum or gold. However, in other embodiments, the bond-wires 5 may be made from other conductive materials. As just one example, copper may be used for the bond-wires 5.

For reference purposes, the size of the package in FIG. 1 is 18 mm in diameter by 5 mm in height. Other embodiments may be other sizes or shapes. However, as will be appreciated, each of the embodiments disclosed herein is packaged in the same dimensions. This allows complete interchangeability between the different embodiments at the upper level assembly. It also allows the same components to be manufactured and used on the various different embodiments, thus increasing flexibility and decreasing costs.

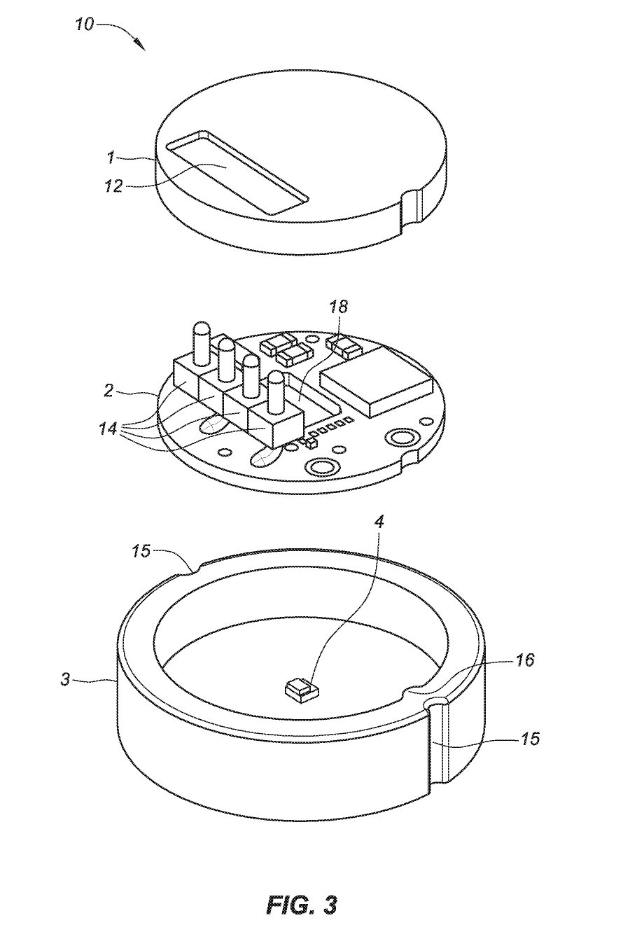

FIG. 3 illustrates an isometric exploded view of the embodiments of a sensor package 10 of FIGS. 1 and 2. In FIG. 3, the cap 1, circuit board 2 and base 3 can all be seen more clearly because they are separated in exploded fashion from their normal assembly configuration.

The embodiment shown in FIG. 3 includes a base 3 that is made from a single piece of ceramic. As will be appreciated as the other embodiments are explained below, the base 3 may be constructed from a plurality of pieces. In this case, the base 3 may be formed in the cup shape shown or may be made as a solid cylinder and then machined into the cup shape as shown.

As explained above, the sensor 4 is mounted directly to the base 3, preferably in the center. The circuit board 2 fits down on top of the sensor 4 with the sensor 4 extending up through the hole 18 in the circuit board 2. The cap 1 fits down on top of the circuit board 2 with the pins 14 extending up through the window 12 in the cap 1.

In preferred embodiments the circuit board 2 and the cap 1, may be coupled to the base using Epoxy or Room Temperature Vulcanized Silicon (RTV). In yet other embodiments, other types of adhesives may be used. In still yet other embodiments, fasteners or interference fits may be used. In the embodiments shown, the circuit board 2 is coupled directly to the bottom of the cavity of the base using epoxy. Similarly, the cap 1 is coupled directly to the walls of the base using epoxy.

The embodiment shown in FIGS. 1-3 is generally for use for air and non-corrosive applications only. The sensor is coupled to a ceramic base 3, a signal conditioning printed circuit board assembly (PCBA) 2 is attached to the ceramic base 3 leaving a hole 18 for the sensor 4 to extend through. A high thermoplastic cap 1 is coupled on top of the PCBA. In preferred embodiments, the PCBA is FR4 grade (Flame Retardant in compliance with standard UL94V-0).

FIG. 4 illustrates an isometric explode view of a second embodiment of a sensor package 20. The embodiment of FIG. 4 is identical to the embodiment of FIGS. 1-3 except in the embodiment of FIG. 4, the base is comprised of two pieces. As shown in FIG. 4, the base is comprised of platform 24 and a ring spacer 22. The platform 24 and ring 22 are both generally cylindrically shaped as was the base in FIGS. 1-3. The platform 24 is a flat cylinder while the ring spacer 22 is shaped like a ring, a cylinder with a concentric hole through the middle to create the ring. In the embodiment shown in FIG. 4, the sensor 4 is mounted to the center of the platform 24. Similar to the embodiments discussed in FIGS. 1-3, the parts of assembly 20 may be attached with epoxy or RTV silicone or other types of adhesives or connectors similar to the sensor package 10 of FIGS. 1-3.

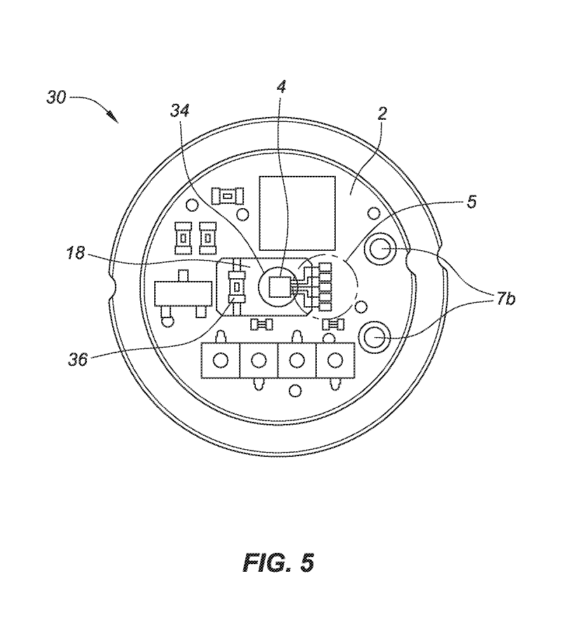

FIG. 5 illustrates a top down view of a third embodiment of a sensor package 30 without the cap shown. The embodiment shown in FIG. 5 is similar to the embodiment shown in FIG. 4 however, the sensor package 30 of FIG. 5 incorporates a temperature sensor 36. Accordingly, the embodiment shown in FIG. 5 has the added capability of sensing temperature. In preferred embodiments, a thermistor is used as the temperature sensor 36 but other types of temperature sensors 36 may be used. As may be seen in FIG. 5, along with the sensor 4, a temperature sensor 36 may also be assembled to the base 34. In preferred embodiments, the temperature sensor 36 is surface mounted directly onto the base 34.

As may be seen in FIG. 5, the temperature sensor 36 is mounted on the top side of the platform 34, the same side as the sensor 4. Consequently, once assembled, both the temperature sensor 36 and the sensor 4, which is preferably a pressure sensor, are both mounted internally to the sensor package assembly 30.

In the embodiment of FIG. 5, both the temperature sensor 36 and sensor 4 are accessible through the window 18 in the circuit board 2. In the embodiment shown in FIG. 5, a single window 18 accommodates both the temperature sensor 36 and the sensor 4. However, in other embodiments, more than one window may be used. Preferably, all the circuit boards 2 for the various embodiments are built with the exact same window configuration and the thermistor is either present or it is not. This cuts down on manufacturing costs.

The embodiment shown in FIG. 5 further includes contact pads 7b located on the circuit board 2. The contact pads 7b provide electrical communication between the temperature sensor 36 located on the base 4 and the electronics of the circuit board 2.

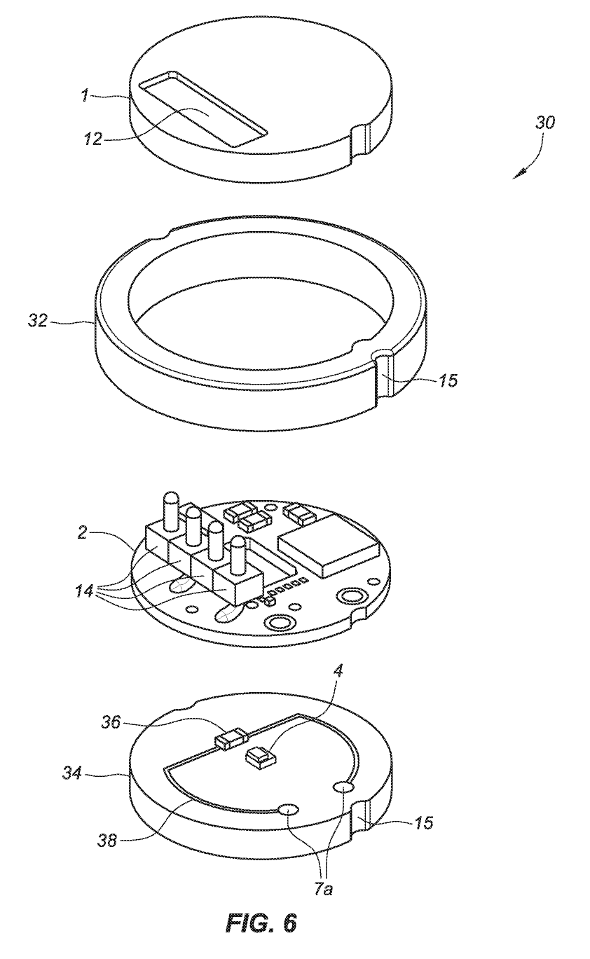

FIG. 6 illustrates an isometric explode view of the embodiment of a sensor package 30 of FIG. 5. As may be seen in FIG. 6, the base of this embodiment is constructed of two pieces 32 and 34, similar to the embodiment shown in FIG. 4. On the platform portion 34 of the base, both a temperature sensor 36 and a sensor 4 are mounted. In the embodiment shown in FIG. 6, the platform 34 includes electrical traces 38 and additional contact pads 7a. both on the top side of the platform 34. The contact pads 7a on the platform 34 align with the contact pads 7b on the circuit board 2 when the two are assembled. This provides electrical communication between the platform 34 and the circuit board 2. The contact pads 7a and 7b may be attached by soldering (SAC305 SMT process). The electrical traces 38 place the contact pads 7a in electrical communication with the thermal sensor 36. The electrical traces 38 may be created using thick film printing or other methods of creating electrical traces.

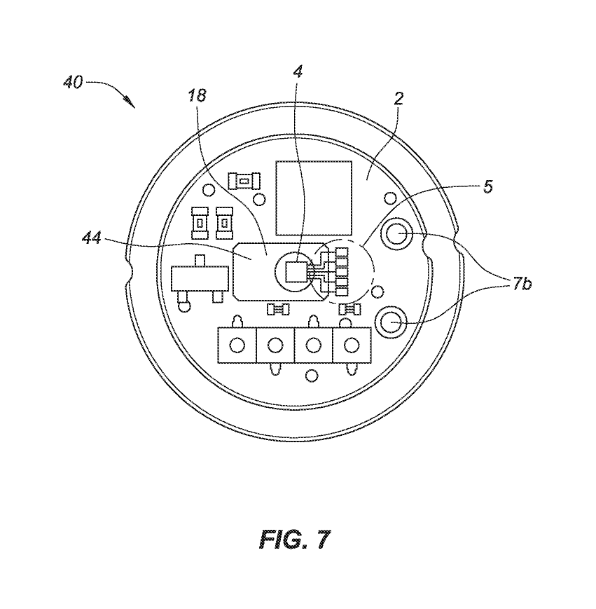

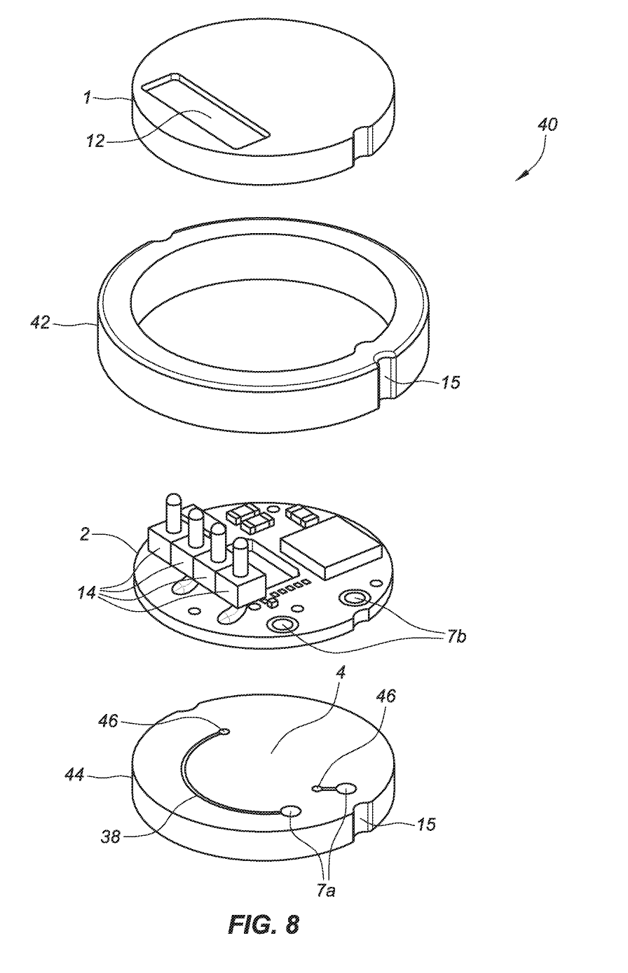

FIG. 7 illustrates a top down view of a fourth embodiment of a sensor package 40 without the cap 1 shown. The embodiment in FIG. 7 is similar in function to the embodiment of FIGS. 5 and 6. The difference is that the embodiment of FIG. 7 is designed to allow a thermal sensor to be mounted on the exterior of the sensor package assembly 40. As may be seen in the exploded view of FIG. 8, the platform 44 includes a plurality of contact pads 7a on the top surface of the base platform 44 that mount with the contact pads 7b on the circuit board 2. The embodiment shown in FIGS. 7-9 also includes electrical traces 38 on the top surface of the base platform 44. In this embodiment, the traces 38 connect the contact pads 7a to through vias 46. The vias 46 pass from the top side of the base platform 44 through the thickness of the base platform 44 to the bottom side.

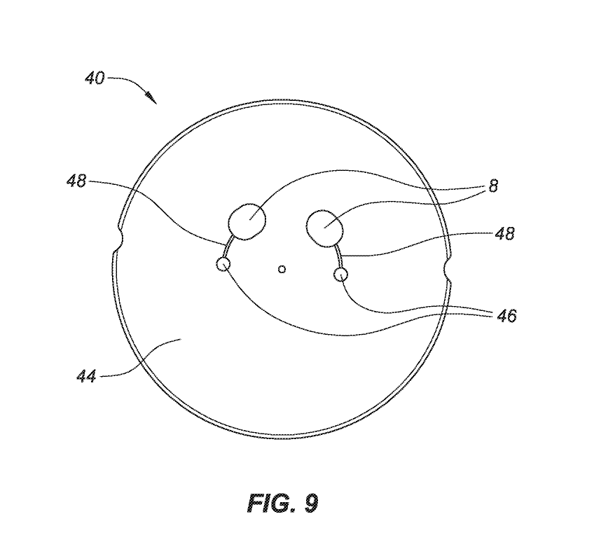

FIG. 9 illustrates a bottom up view of the embodiment of FIGS. 7 and 8. As may be seen, the vias 46 pass through to the bottom of the base platform 44. The base platform 44 also has electrical traces 48 on the bottom side and more contact pads 8. The contact pads are spaced and designed to receive a thermal sensor (not shown). The traces 48 provide electrical communication between the vias 46 and the contact pads 8 on the bottom side of the base platform 44.

Although the inventions have been described with reference to preferred embodiments and specific examples, it will readily be appreciated by those skilled in the art that many modifications and adaptations of the apparatus and methods described herein are possible without departure from the spirit and scope of the inventions as claimed hereinafter. Thus, it is to be clearly understood that this description is made only by way of example and not as a limitation on the scope of the embodiments as claimed hereafter.

What is claimed is:

1. A sensor package comprising:
a ceramic base wherein the base is comprised of a platform and walls that extend up from the platform around a periphery of the platform to form a cavity;
a sensor mounted to the ceramic base on a bottom surface of the cavity;
a circuit board mounted down into the cavity wherein the circuit board has a hole through the circuit board that aligns with the sensor such that the sensor is exposed to a top side of the circuit board through the hole;
a plurality of electrical connections between the sensor and the circuit board;
a plurality of electrical pins mounted to the circuit board and extending up above the walls of the ceramic base; and
a cap mounted down into the cavity over the top of the circuit board, the cap including a window that allows the electrical pins to pass through the cap and extend above the cap.

2. The sensor package of claim 1, wherein the cap is made from a thermal plastic.

3. The sensor package of claim 1, wherein the sensor is a MEMS sensor.

4. The sensor package of claim 3, wherein the sensor is a pressure sensor.

5. The sensor package of claim 1, wherein the ceramic base is made from two pieces coupled together, the first piece comprises the platform and the second piece comprises the walls.

6. The sensor package of claim 1, wherein the base is made from Alumina Oxide.

7. The sensor package of claim 1, further comprising a thermal sensor mounted to the base.

8. The sensor package of claim 7 wherein the thermal sensor is mounted on the bottom surface of the cavity and wherein the thermal sensor is aligned with the hole in the circuit board such that the thermal sensor is exposed to the top side of the circuit board through the hole.

9. The sensor package of claim 7 wherein the thermal sensor is mounted on a bottom surface of the platform portion of the base and vias through the platform provide electrical communication between the thermal sensor and the circuit board.

10. The sensor package of claim 7, further comprising a first set of electrical contact pads on the bottom surface of the cavity of the base and a corresponding second set of electrical contact pads on the circuit board wherein the first and second sets of electrical contact pads are aligned to provide electrical communication between the circuit board and the thermal sensor.

11. The sensor package of claim 1, wherein the base, cap and circuit board are cylindrical.

12. A method of assembling a sensor in a sensor package comprising:
soldering a sensor to a bottom surface of a cavity in a ceramic base wherein the base is comprised of a platform and walls that extend up from the platform around the periphery of the platform to form the cavity;
epoxying a circuit board down into the cavity of the base such that a hole in the circuit board surrounds the sensor;
electrically connecting the sensor to the circuit board with bond-wires; and
epoxying a cap down into the cavity of the base such that the cap covers the circuit board wherein the cap has a window and connection pins mounted to the circuit board extend up past the top of the walls and the cap through the window.

13. The method of claim 12, wherein the cap is made from a thermal plastic.

14. The method of claim 12, wherein the sensor is a MEMS sensor.

15. The method of claim 12, wherein the sensor is a pressure sensor.

16. The method of claim 12, wherein the ceramic base is made from two pieces, a first piece comprises the platform and a second piece comprises the walls and the method further comprises coupling the platform to the walls.

17. The method of claim 12, wherein the base is made from Alumina Oxide.

18. The method of claim 12, further comprising mounting a thermal sensor to the base.

19. The method of claim 18, wherein the thermal sensor is mounted on the bottom surface of the cavity and wherein the thermal sensor is aligned with the hole in the circuit board such that the thermal sensor is exposed to the top side of the circuit board through the hole.

20. The method of claim 18, wherein the thermal sensor is mounted on a bottom surface of the platform portion of the base and vias through the platform provide electrical communication between the thermal sensor and the circuit board.

21. The method of claim 18, further comprising placing the circuit board in electrical communication with the thermal sensor by aligning a first set of electrical contact pads on the bottom surface of the cavity of the base and a corresponding second set of electrical contact pads on the circuit board.

22. The method of claim 12, wherein the base, cap and circuit board are cylindrical.

23. The method of claim 18, wherein the thermal sensor is a thermistor.
